(19) United States
(12) Patent Application Publication
(10) Pub. No.: US 2025/0149396 A1
(43) Pub. Date: May 8, 2025

(54) PACKAGE STRUCTURE

(71) Applicant: Advanced Semiconductor Engineering, Inc., Kaohsiung (TW)

(72) Inventors: Po-Jen CHENG, Kaohsiung (TW); Wei-Jen WANG, Kaohsiung (TW); Wei-Long CHEN, Kaohsiung (TW); Hao-Chung WANG, Kaohsiung (TW); Kai-Wen CHAN, Kaohsiung (TW)

(73) Assignee: Advanced Semiconductor Engineering, Inc., Kaohsiung (TW)

(21) Appl. No.: 18/501,956

(22) Filed: Nov. 3, 2023

(51) Int. Cl. H01L 23/31; H01L 23/00; H01L 23/498; H01L 25/10

(52) U.S. Cl. CPC H01L 23/3157; H01L 23/49816; H01L 23/49838; H01L 24/16; H01L 24/32; H01L 24/73; H01L 25/105; H01L 2224/16225; H01L 2224/32059; H01L 2224/32225; H01L 2224/73204

(57) ABSTRACT

A package structure is provided. The package structure includes a substrate, a first electronic component, a first electrical connector, and a protective layer. The first electronic component is over the substrate. The first electrical connector is between the substrate and the first electronic component. The protective layer encapsulates the first electrical connector. The protective layer has a first curved lateral surface concave toward the first electrical connector and recessed with respect to a lateral surface of the first electronic component.

### BACKGROUND

### 1. Technical Field

The present disclosure relates generally to a package structure, and particularly to a package structure including a protective layer.

### 2. Description of the Related Art

In stacked structures such as electronic components electrically connected to a substrate, minimal solder may be used to prevent the solder from bridging. However, it is difficult for underfill to flow between the layers to cover and protect the soldering, since the space is minimized. In addition, the underfill may overflow toward solder ball pads, reducing yield.

### SUMMARY

In one or more arrangements, a package structure includes a substrate, a first electronic component, a first electrical connector, and a protective layer. The first electronic component is over the substrate. The first electrical connector is between the substrate and the first electronic component. The protective layer encapsulates the first electrical connector. The protective layer has a first curved lateral surface concave toward the first electrical connector and recessed with respect to a lateral surface of the first electronic component.

In one or more arrangements, a package structure includes a substrate, a first electronic component, a second electronic component, and a protective layer. The substrate has a first surface and a second surface opposite to the first surface. The first electronic component is disposed over the first surface. The second electronic component is disposed under the second surface of the substrate. The protective layer is between the first electronic component and the substrate. The protective layer has a cavity space at least partially overlapping a path between the first electronic component and the second electronic component, and the cavity space is configured to reduce transmission of heat generated by the second electronic component and transmitted toward the first electronic component.

In one or more arrangements, a package structure includes a substrate, an electronic component, and a protective layer. The substrate includes a first conductive pad and a second conductive pad, and the second conductive pad is exposed by a first opening of the substrate. The electronic component is electrically connected to the first conductive pad. The protective layer is between the substrate and the electronic component. The first opening of the substrate is at a first lateral side of the protective layer. A first ratio of a distance between the protective layer and the first opening of the substrate with respect to a distance between the substrate and the electronic component is less than 25.

### BRIEF DESCRIPTION OF THE DRAWINGS

Aspects of the present disclosure are better understood from the following detailed description when read with the accompanying drawings. It is noted that various features may not be drawn to scale, and the dimensions of the various features may be arbitrarily increased or reduced for clarity of discussion.

FIG. 1 is a cross-section of a package structure in accordance with some arrangements of the present disclosure.

FIG. 1A is a cross-section of a portion of a package structure in accordance with some arrangements of the present disclosure.

FIG. 1B is a top view of a portion of a package structure in accordance with some arrangements of the present disclosure.

FIG. 2A is a cross-section of a package structure in accordance with some arrangements of the present disclosure.

FIG. 2B is a cross-section of a portion of a package structure in accordance with some arrangements of the present disclosure.

FIG. 2C is a cross-section of a package structure in accordance with some arrangements of the present disclosure.

FIG. 2D is a cross-section of a portion of a package structure in accordance with some arrangements of the present disclosure.

FIG. 3A is a cross-section of a package structure in accordance with some arrangements of the present disclosure.

FIG. 3B is a cross-section of a package structure in accordance with some arrangements of the present disclosure.

FIG. 4A, FIG. 4B, FIG. 4C, FIG. 4D, FIG. 4E, FIG. 4F, and FIG. 4G illustrate various stages of an exemplary method for manufacturing a package structure in accordance with some embodiments of the present disclosure.

FIG. 5A, FIG. 5B, FIG. 5C, FIG. 5D, and FIG. 5E illustrate various stages of an exemplary method for manufacturing a package structure in accordance with some embodiments of the present disclosure.

Common reference numerals are used throughout the drawings and the detailed description to indicate the same or similar elements. The present disclosure will be more apparent from the following detailed description taken in conjunction with the accompanying drawings.

### DETAILED DESCRIPTION

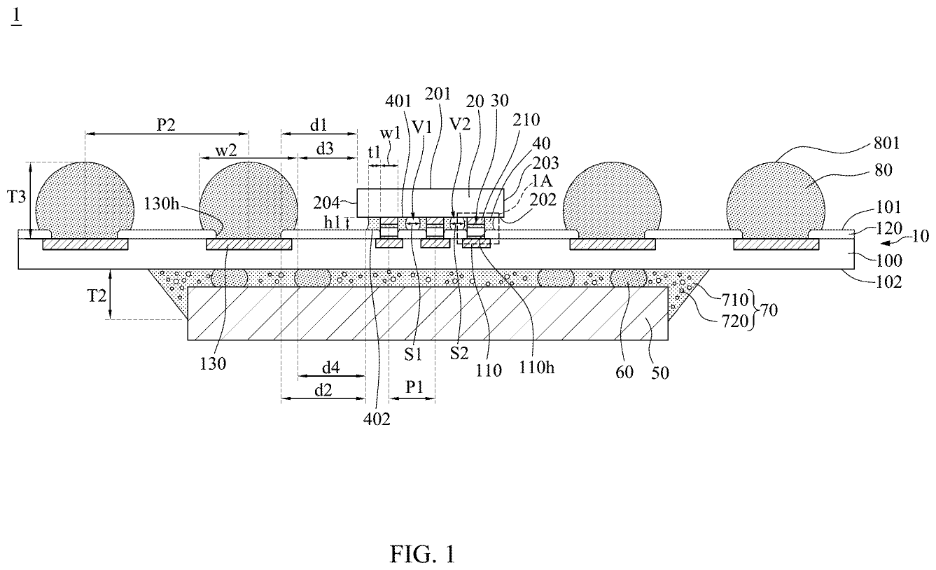

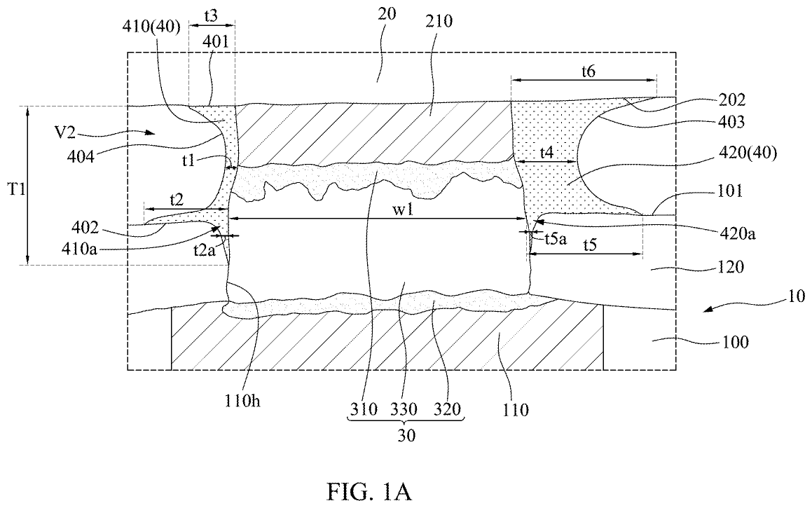

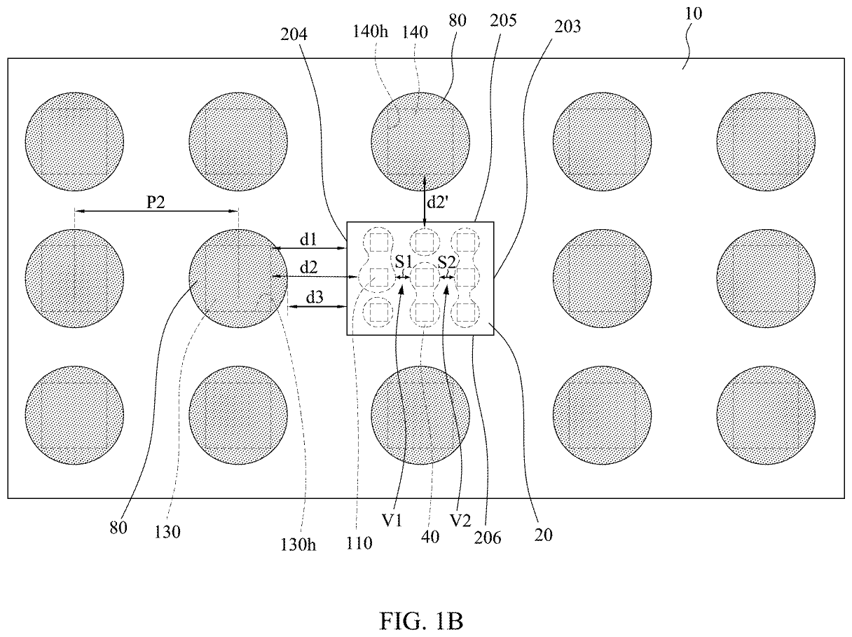

FIG. 1 is a cross-section of a package structure 1 in accordance with some arrangements of the present disclosure. FIG. 1A is a cross-section of a portion of a package structure 1 in accordance with some arrangements of the present disclosure. FIG. 1B is a top view of a portion of a package structure 1 in accordance with some arrangements of the present disclosure. In some arrangements, FIG. 1A is a cross-section of a portion 1A of the package structure 1 illustrated in FIG. 1. In some arrangements, FIG. 1B is a top view of the package structure 1 illustrated in FIG. 1. The package structure 1 may include a substrate 10, electronic components 20 and 50, electrical connectors 30 and 60, a protective layer 40, an underfill 70, and electrical contacts 80.

The substrate 10 may include, for example, a printed circuit board, such as a paper-based copper foil laminate, a composite copper foil laminate, or a polymer-impregnated glass-fiber-based copper foil laminate. The substrate 10 may include an interconnection structure, which may include a plurality of conductive traces and/or conductive vias. The interconnection structure may include a redistribution layer (RDL) and/or a grounding element. In some arrangements, the substrate 10 may include an organic substrate or a leadframe. In some arrangements, the substrate 10 may include a ceramic material or a metal plate. In some arrangements, the substrate 10 may include a two-layer substrate which includes a core layer and a conductive material and/or structure disposed on an upper surface and a bottom surface of the substrate. The substrate 10 may include a semiconductor wafer or an electronic component. The electronic component may be a chip or a die including a semiconductor substrate, one or more integrated circuit devices, and one or more overlying interconnection structures therein. The integrated circuit devices may include active devices such as transistors and/or passive devices such resistors, capacitors, inductors, or a combination thereof. In some arrangements, the substrate 10 may include one or more conductive elements, surfaces, contacts, or pads.

In some arrangements, the substrate 10 has a surface 101 and a surface 102 opposite to the surface 101. In some arrangements, referring to FIGS. 1, 1A, and 1B, the substrate 10 includes a base layer 100, a dielectric layer 120, and conductive pads 110, 130, and 140. The conductive pads 110, 130, and 140 may be exposed by the surface 101. In some arrangements, the conductive pads 110 are exposed by opening 110h of the substrate 10 (or the dielectric layer 120). In some arrangements, the conductive pads 130 are exposed by opening 130h of the substrate 10 (or the dielectric layer 120). In some arrangements, the conductive pads 130 are at a lateral side of the electronic component 20. In some arrangements, a distance between the conductive pad 110 and one of the conductive pads 130 is less than a pitch of the conductive pads 130. In some arrangements, referring to FIG. 1B, the conductive pads 140 are exposed by opening 140h of the substrate 10 (or the dielectric layer 120). In some arrangements, a width of the conductive pad 130 is greater than a width of the conductive pad 110. In some arrangements, a width of the conductive pad 140 is greater than a width of the conductive pad 110.

The electronic component 20 may be disposed over the substrate 10. The electronic component 20 may be disposed over the conductive pad 110. The electronic component 20 may have a surface 201, a surface 202 opposite to the surface 201, and lateral surfaces 203, 204, 205, and 206. The lateral surface 203 may be opposite to the lateral surface 204, and the lateral surface 205 may be opposite to the lateral surface 206. The surface 202 may face the substrate 10. The surface 202 may be referred to as an active surface or a bottom surface of the electronic component 20. In some arrangements, the electronic component 20 includes conductive pads 210. The conductive pads 210 may be disposed on or protrude beyond the surface 202. In some arrangements, the electronic component 20 is electrically connected to the conductive pad 110. For example, the conductive pads 210 may be electrically connected to the conductive pads 110. In some arrangements, the conductive pads 110 and the openings 110h are directly under the electronic component 20. In some arrangements, the conductive pads 130 and the conductive pads 140 are at adjacent sides (e.g., the adjacent lateral surfaces 204 and 205) of the electronic component 20. In some arrangements, the openings 130h and the openings 140h are at adjacent sides (e.g., the adjacent lateral surfaces 204 and 205) of the electronic component 20. The electronic component 20 may be or include a passive die such as resistors, capacitors, inductors, or a combination thereof, or any other type of passive dies. The electronic component 20 may be or include an active die such as an ASIC or any other type of active dies. In some arrangements, the electronic component 20 may be or include an integrated passive device (IPD).

The electrical connectors 30 may be disposed between the substrate 10 and the electronic component 20. In some arrangements, the electrical connector 30 connects or electrically connects the conductive pad 110 to the conductive pad 210. Referring to FIG. 1A, the electrical connector 30 includes a solder element 330, an intermediate layer 310 between the conductive pad 110 and the solder element 330, and an intermediate layer 320 between the conductive pad 210 and the solder element 330. The solder element 330 may include a soldering materials, e.g., Sn. The intermediate layers 310 and 320 may include one or more intermetallic compounds (IMCs). In some arrangements, the intermediate layer 310 includes an IMC of the metals from the conductive pad 110 and the solder element 330. In some arrangements, the intermediate layer 320 includes an IMC of the metals from the conductive pad 210 and the solder element 330. In some arrangements, the electrical connector 30 is partially within or embedded in the substrate. In some arrangements, the electrical connector 30 is partially within the opening 110h of the substrate 10 (or the dielectric layer 120). The electrical connectors 30 may include conductive bumps. The conductive bumps may include gold (Au), silver (Ag), copper (Cu), another metal, a solder alloy, or a combination of two or more thereof.

The protective layer 40 may be between the substrate 10 and the electronic component 20. In some arrangements, the protective layer 40 is between the conductive pads 110 and the electronic component 20. In some arrangements, the protective layer 40 encapsulates the electrical connectors 30. In some arrangements, the protective layer 40 is free of fillers. In some arrangements, the protective layer 40 is formed of or includes epoxy flux. The epoxy flux includes an epoxy resin and a solder flux material. In some arrangements, a viscosity of the protective layer 40 equals or exceeds about 20 Pa·S. In some arrangements, a viscosity of the protective layer 40 is from about 20 Pa·S to about 35 Pa·S. In some arrangements, a modulus of the protective layer 40 is less than about 9 GPa, 7 GPa, 5 GPa, or 3 GPa. In some arrangements, a modulus of the protective layer 40 may be about 2 GPa.

In some arrangements, the protective layer 40 has a surface 401, a surface 402 opposite to the surface 401, and lateral surfaces 403 and 404 (also referred to as “curved lateral surfaces”) concave toward the electrical connectors 30. In some arrangements, the lateral surfaces 403 and 404 are concave or at least partially concave toward a space between the substrate 10 and the electronic component 20. In some arrangements, the lateral surfaces 403 and 404 are concave or at least partially concave toward the intermediate layer 310 of the electrical connector 30. In some arrangements, the lateral surface 403 (or the curved lateral surface) is recessed or at least partially recessed with respect to the lateral surface 203 of the electronic component 20. In some arrangements, the lateral surface 404 (or the curved lateral surface) is recessed or at least partially recessed with respect to the lateral surface 204 of the electronic component 20. In some arrangements, a curvature of the lateral surface 403 is different from a curvature of the lateral surface 404.

In some arrangements, the protective layer 40 has one or more cavity spaces (e.g., cavity spaces V1 and V2). The one or more cavity spaces may be located at or at least partially overlap a path between the electronic component 20 and the electronic component 50. In some arrangements, the cavity spaces are configured to reduce heat transmission from the electronic component 50 toward the electronic component 20. In some arrangements, the cavity spaces are configured to reduce transmission of heat generated by the electronic component 50 and transmitted toward the electronic component 20. In some arrangements, a plurality of voids (e.g., the cavity spaces V1 and V2) are formed within the protective layer 40 and between the electrical connectors 30. In some arrangements, at least two of the voids have different widths. For example, a width S1 of the cavity space V1 is different from a width S1 of the cavity space V2. The cavity spaces may be referred to as voids, air spaces, pores, or the like. In some arrangements, the intermediate layer 310 horizontally overlaps the cavity space V1. In some arrangements, referring to FIG. 1B, the two or more of the cavity spaces (e.g., the cavity spaces V1 and V2) are connected. In some arrangements, the protective layer 40 is partially spaced apart from one or more of the electrical connectors 30 by one or more of the cavity spaces. In some arrangements, the protective layer 40 includes a plurality of segments spaced apart from one another by the cavity spaces V1 and V2. In some arrangements, a segment of the protective layer 40 is spaced apart from one or more of the electrical connectors 30 by one or more of the cavity spaces V1 and V2. In some arrangements, a region of the surface 202 (or the active surface) of the electronic component 20 is exposed by the protective layer 40 and between adjacent electrical connectors 30 in a cross-sectional view perspective. The region of the surface 202 may be exposed to the cavity space. In some arrangements, a corner region of the surface 202 (or the bottom surface) of the electronic component 20 is exposed by the protective layer 40,

Referring to FIG. 1A, in some arrangements, the protective layer 40 includes portion 410 and 420 on opposite sides (e.g., distinct lateral sides) of the electrical connector 30 in a cross-sectional view perspective. In some arrangements, the portions 410 and 420 are geometrically distinct from each other. In some arrangements, the portion 410 and the portion 420 have different widths at the same elevation. For example, the portion 410 may have various widths t1, t2, and t3 at different elevations, and the portion 420 may have various widths t4, t5, and t6 at different elevations. In some arrangements, the width t1 and the width t4 are at the same elevation and are different. In some arrangements, the width t2 and the width t5 are at the same elevation and are different. In some arrangements, the width t3 and the width t6 are at the same elevation and are different.

In some arrangements, the width t1 is less than the widths t2 and t3. In some arrangements, a ratio t1/t2 is less than about 0.2, and a ratio t1/t3 is less than about 0.3. In some arrangements, the width t4 is less than the widths t5 and t6. In some arrangements, a ratio t4/t5 is less than about 0.6. In some arrangements, a ratio t4/t6 is less than about 0.6. In some arrangements, a ratio S1/P1 of the width S1 of the cavity space V1 with respect to a pitch P1 of the electrical connectors 30 may be less than about 0.6.

Referring to FIG. 1A, in some arrangements, the protective layer 40 is partially disposed between the substrate 10 and the electrical connector 30. In some arrangements, the protective layer 40 may include one or more protrusions (e.g., protrusions 410a and 420a) disposed between the substrate 10 and the electrical connector 30. The protrusions 410a and 420a may horizontally overlap the substrate 10. In some arrangements, the protrusion 410a is geometrically distinct from the protrusion 420a. In some arrangements, the protrusions 410a and 420a have different widths at the same elevation. For example, a width t2a of the protrusion 410a and a width t5a of the protrusion 420a may be at the same elevation and different. In some arrangements, the protrusions 410a and 420a are between the substrate and the solder element 330 of the electrical connector 30. In some arrangements, the intermediate layer 320 of the electrical connector 30 partially overlaps the protrusion 410a and/or the protrusion 420a.

In some arrangements, referring to FIG. 1B, the conductive pads 130 and the conductive pads 140 are at adjacent sides of the protective layer 40. In some arrangements, referring to FIG. 1B, the openings 130h and the openings 140h are at adjacent sides of the protective layer 40.

The electronic component 50 may be disposed under the surface 102 of the substrate 10. In some arrangements, a width of the electronic component 50 is greater than a width of the electronic component 20. The electronic component 50 may be or include a passive die such as resistors, capacitors, inductors, or a combination thereof, or any other type of passive dies. The electronic component 50 may be or include an active die such as an ASIC or any other type of active dies. In some arrangements, the electronic component 50 may be or include a processor die, such as an ASIC.

The electrical connectors 60 may be disposed between the electronic component 50 and the substrate 10. In some arrangements, the electronic component 50 is electrically connected to the substrate 10 through the electrical connectors 60. In some arrangements, a thickness of the electrical connector 30 is less than a thickness of the electrical connector 60. In some arrangements, a pitch of the electrical connectors 60 is greater than a distance between the conductive pad 110 and one of the conductive pads 130. The electrical connectors 60 may include conductive bumps. The conductive bumps may include gold (Au), silver (Ag), copper (Cu), another metal, a solder alloy, or a combination of two or more thereof.

The underfill 70 may be disposed between the substrate 10 and the electronic component 50. In some arrangements, the underfill 70 encapsulates the electrical connectors 60. In some arrangements, the underfill 70 includes a resin layer 710 and a plurality of fillers 720. In some arrangements, a thickness T2 of the underfill 70 is greater than a thickness T1 of the protective layer 40. In some arrangements, a modulus of the underfill 70 is greater than a modulus of the protective layer 40. In some arrangements, a viscosity of the underfill 70 is less than a viscosity of the protective layer 40. In some arrangements, a viscosity of the underfill 70 is equal to or less than about 20 Pa·S. In some arrangements, a viscosity of the underfill 70 is about 20 Pa·S. In some arrangements, a modulus of the underfill 70 is greater than about 3 GPa, 7 GPa, 5 GPa, or 9 GPa. In some arrangements, a modulus of the underfill 70 may be about 9 GPa.

The electrical contacts 80 (also referred to as “electrical connectors”) may be disposed at one or more lateral sides of the protective layer 40. In some arrangements, the electrical contacts 80 are disposed on the conductive pads 140. In some arrangements, the electrical contacts 80 are electrically connected to the conductive pads 140. In some arrangements, an elevation of a top surface 801 of the electrical contact 80 is higher than an elevation of a top surface (e.g., the surface 401) of the protective layer 40 with respect to the substrate 10. In some arrangements, the elevation of the top surface 801 of the electrical contact 80 is higher than an elevation of a top surface (e.g., the surface 201) of the electronic component 20 with respect to the substrate 10. In some arrangements, the electrical contacts 80 horizontally overlap the electronic component 20. In some arrangements, the electrical contacts 80 are disposed at one or more lateral sides of the electronic component 20 and horizontally overlapping the electrical connectors 30. In some arrangements, a thickness T3 of the electrical contact 80 is greater than a thickness of the electrical connector 60. The electrical contacts 80 may be or include solder balls. For example, the electrical contacts 80 may include controlled collapse chip connection (C4) bumps, a ball grid array (BGA), or a land grid array (LGA).

The conductive layers, pads, pillars, and/or vias may independently include a conductive material such as a metal or metal alloy. Examples include gold (Au), silver (Ag), aluminum (Al), copper (Cu), or an alloy thereof. The dielectric layers may independently include an organic material, a solder mask, PI, an ABF, one or more molding compounds, one or more pre-impregnated composite fibers (e.g., a pre-preg material), borophosphosilicate glass (BPSG), silicon oxide, silicon nitride, silicon oxynitride, undoped silicate glass (USG), any combination thereof, or the like. The underfills may independently include an epoxy resin, a molding compound (e.g., an epoxy molding compound or other molding compound), polyimide, a phenolic compound or material, a material including a silicone dispersed therein, or a combination thereof.

In some arrangements, the substrate 10 may have a size from about 25*20 mm² to about 30*14 mm², and the electronic component 20 may have a size from about 0.7*0.5 mm² to about 1*0.8 mm². A distance d1 between the opening 130h and the electronic component 20 may be from about 0.185 mm to about 0.205 mm, and a distance d2 between the opening 130h and the protective layer 40 may be from about 0.13 mm to about 0.28 mm. In some arrangements, the substrate 10 may have a size from about 55*35 mm² to about 60*40 mm², and the electronic component 20 may have a size from about 2*1 mm² to about 3*2 mm². A distance d1 may be between the opening 130h and the electronic component 20 may be from about 0.21 mm to about 0.68 mm, and a distance d2 between the opening 130h and the protective layer 40 may be from about 0.25 mm to about 0.52 mm.

In some cases where an electronic component is bonded to a substrate through solder bumps (e.g., the electrical connectors 30) followed by applying an underfill to encapsulate the solder bumps, the underfill may overflow toward conductive pads (also referred to as “solder ball pads”) for solder balls (e.g., the conductive pads 130 for the electrical contacts 80). Once the solder ball pads are covered by the underfill, the solder balls cannot be bonded to the solder ball pads. To prevent the aforesaid issues, a keep out zone (KOZ) is required between the solder ball pads and the solder bumps. For a substrate having a size from about 25*20 mm² to about 30*14 mm² and an electronic component having a size from about 0.7*0.5 mm² to about 1*0.8 mm², the KOZ is required to be at least from about 1*0.6 mm² to about 1.5*2 mm². For a substrate having a size from about 55*35 mm² to about 60*40 mm² and an electronic component having a size from about 2*1 mm² to about 3*2 mm², the KOZ is required to be at least from about 2*1 mm² to about 3.5*2.5 mm².

In contrast, according to some arrangements of the present disclosure, the electrical connectors 30 are encapsulated by the protective layer 40 having one or more curved lateral surfaces concave toward the electrical connectors 30, the KOZ can be significantly reduced. For example, the distance d1 between the electronic component 20 and the opening 130h directly above the conductive pad 130 is from about 0.185 mm to about 0.205 mm or from about 0.21 mm to about 0.68 mm, which is significantly less than the aforementioned size of the KOZ. In addition, with the design of the protective layer 40, the relationship between various dimensions of elements of the package structure 1 may have the following properties.

A distance d2′ may be between the opening 140h and the protective layer 40, and a distance h1 may be between the electronic component 20 and the substrate 10. The electrical connector 30 may have a width w1. The electronic connectors 30 may have a pitch P1. In some arrangements, a ratio d1/h1 of the distance d1 between the opening 130h and the electronic component 20 with respect to the distance h1 is less than about 25, for example, from 5 to less than 25, from 10 to 20, or from 11 to 14. In some arrangements, a ratio d1/P1 of the distance d1 with respect to the pitch P1 is less than about 5, for example, from 1 to less than 5, from 1.5 to 3, or from 1 to 2. In some arrangements, a ratio d1/t1 of the distance d1 with respect to the width t1 is less than about 25, for example, from 1 to less than 25, from 3 to 20, or from 5 to 10. In some arrangements, a ratio d1/w1 of the distance d1 with respect to the width w1 is less than about 10, for example, from 1 to less than 10, from 2 to 8, or from 3 to 10. In some arrangements, a ratio d2/h1 of the distance d2 between the protective layer 40 and the opening 130h of the substrate 10 with respect to the distance h1 between the substrate 10 and the electronic component 20 is less than about 25, for example, from 8 to less than 25, from 10 to 20, or from 11 to 15. In some arrangements, a ratio d2′/h1 of the distance d2′ between the protective layer 40 and the opening 140h of the substrate 10 with respect to the distance h1 is less than about 25, for example, from 8 to less than 25, from 10 to 20, or from 11 to 15. In some arrangements, the ratio d2/h1 may be different from the ratio d2′/h1. In some arrangements, a ratio d2/P1 of the distance d2 with respect to the pitch P1 is less than about 3, for example, from 1 to less than 3, from 1 to 2.5, or from 1.5 to 2. In some arrangements, a ratio d2/t1 of the distance d2 with respect to the width t1 is less than about 45, for example, from 0.5 to less than 45, from 5 to 30, or from 7.5 to 15. In some arrangements, a ratio d2/w1 of the distance d2 with respect to the width w1 is less than about 8, for example, from 2 to less than 8, from 3 to 6.5, or from 3.5 to 4.5.

In some examples, the ratio d2/h1 may be greater than 25, such that the distance d2 between the protective layer 40 and the opening 130h of the substrate 10 may be relatively large, or the distance h1 between the substrate 10 and the electronic component 20 may be relatively small. When the distance d2 is relatively large, the keep out zone (KOZ) may be also enlarged. As a result, the size of the package structure is undesirably increased. Alternatively, when the distance h1 (i.e., the gap remained between the electronic component 20 and the substrate 10) is too small, the processing window for bonding the electronic component 20 to the substrate 10 may be relatively small, such that the difficulty and complexity of the manufacturing process is increased, and the yield may be decreased.

According to some arrangements of the present disclosure, the ratio d2/h1 may be less than about 25, for example, from 8 to less than 25. Therefore, the KOZ can be significantly reduced without increasing the difficulty and complexity of the manufacturing process. Accordingly, the size of the package structure 1 can be reduced without decreasing the yield. Similarly, the ratio d2′/h1 being less than about 25 may be provided with similar effects described above.

In some examples, the ratio d2/h1 may be less than 8, such that the distance d2 between the protective layer 40 and the opening 130h of the substrate 10 may be relatively small, or the distance h1 between the substrate 10 and the electronic component 20 may be relatively large. When the distance d2 is relatively small, the keep out zone (KOZ) may be too small to prevent the material of the protective layer from overflowing toward the conductive pad 130 and/or the electrical contact 80 in the manufacturing process. As a result, the yield may decrease significantly. Alternatively, when the distance h1 (i.e., the gap remained between the electronic component 20 and the substrate 10) is too large, the top surface of the electronic component 20 may be higher than the top surface of the electrical contact 80 with respect to the substrate 10, which may block the package structure from bonding to an external component or substrate through the electrical contacts 80 and thus decreasing the yield, or larger electrical contacts 80 having greater heights are required, which may increase the size of the package structure.

According to some arrangements of the present disclosure, the ratio d2/h1 may be equal to or greater than about 8, for example, from 8 to less than 25. Therefore, the KOZ can be significantly reduced without increasing the difficulty and complexity of the manufacturing process. Accordingly, the size of the package structure 1 can be reduced without decreasing the yield. Similarly, the ratio d2′/h1 being less than about 25 may be provided with similar effects described above.

A distance d3 may be between the electrical contact 80 and the electronic component 20, and a distance d4 may be between the electrical contact 80 and the protective layer 40. The electrical contact 80 may have a width w2. The electrical contacts 80 may have a pitch P2. In some arrangements, a ratio d3/h1 of the distance d3 with respect to the distance h1 is less than about 35, for example, from 5 to less than 35, from 10 to 20, or from 12 to 15. In some arrangements, a ratio d3/P1 of the distance d3 with respect to the pitch P1 is less than about 20, for example, from 0.1 to less than 3, from 0.2 to 2, or from 0.3 to 1. In some arrangements, a ratio d3/P2 of the distance d3 with respect to the pitch P2 is less than about 1.8, for example, from 0.1 to less than 1.8, from 0.2 to 1.2, or from 0.3 to 0.6. In some arrangements, a ratio d3/t1 of the distance d3 with respect to the width t1 is less than about 35, for example, from 1 to less than 35, from 3 to 22, or from 5 to 10. In some arrangements, a ratio d3/w1 of the distance d3 with respect to the width w1 is less than about 15, for example, from 1 to less than 15, from 2 to 10, or from 3 to 5. In some arrangements, a ratio d3/w2 of the distance d3 with respect to the width w2 is less than about 3, for example, from 0.0 to less than 3, from 0.5 to 2, or from 0.6 to 1. In some arrangements, a ratio d4/h1 of the distance d4 with respect to the distance h1 is less than about 3.5, for example, from 0.05 to less than 3.5, from 0.1 to 2, or from 0.3 to 1. In some arrangements, a ratio d4/P1 of the distance d4 with respect to the pitch P1 is less than about 0.4, for example, from 0.01 to less than 0.4, from 0.02 to 0.2, or from 0.03 to 0.1. In some arrangements, a ratio d4/P2 of the distance d4 with respect to the pitch P2 is less than about 0.8, for example, from 0.001 to less than 0.8, from 0.005 to 0.6, or from 0.01 to 0.05. In some arrangements, a ratio d4/t1 of the distance d4 with respect to the width t1 is less than about 8, for example, from 0.03 to less than 8, from 0.1 to 4, or from 0.3 to 2. In some arrangements, a ratio d4/w1 of the distance d4 with respect to the width w1 is less than about 0.9, for example, from 0.01 to less than 0.9, from 0.025 to 0.8, or from 0.1 to 0.3. In some arrangements, a ratio d4/w2 of the distance d4 with respect to the width w2 is less than about 0.2, for example, from 0.003 to less than 0.2, from 0.005 to 0.1, or from 0.01 to 0.06.

According to some arrangements of the present disclosure, with the above ratios between the dimensions of elements of the package structure 1, the KOZ between the conductive pads 130 and the electrical connectors 30 (or the KOZ between the electrical contacts 80 and the protective layer 40) can be significantly reduced. Therefore, the package size can be significantly reduced, and more space can be provide for more electrical contacts (i.e., input/output (I/O) counts).

In addition, according to some arrangements of the present disclosure, the protective layer is formed of or includes epoxy flux. The solder flux material of the epoxy flux can clean bonding surfaces of the conductive pads, which is advantageous to increasing the bonding strength between the solder element and the conductive pads. Moreover, the epoxy resin of the epoxy flux can be cured during the reflow operation for the solder elements of the electrical connectors and form the protective layer for the electrical connectors. Therefore, the operation of dispensing an underfill to protect the electrical connector can be omitted, and the abovementioned overflow issue of the underfill can be effectively prevented.

Moreover, according to some arrangements of the present disclosure, the solvent in the solder reflux material may be evaporated during the reflow operation. Therefore, the protective layer can be formed with concave curved lateral surfaces, which are recessed from the lateral surfaces of the electronic component. Accordingly, the KOZ can be reduced or even omitted, and thus the package size can be reduced. In addition, while an underfill material does not form voids during a curing operation, the solvent may evaporate and discharge out of the epoxy flux, voids may be formed within the protective layer, which is advantageous to reducing heat transmission through the substrate toward the electronic component.

In addition, according to some arrangements of the present disclosure, the epoxy flux has a relatively high viscosity compared to an underfill material, and the viscosity of the epoxy flux may increase as the temperature increases, for example, during the reflow operation. Therefore, the protective layer formed from the epoxy flux after the reflow operation may have an increased adhesion strength to the electrical connectors, the substrate, and the electronic component. Accordingly, the protective layer can provide a relatively high encapsulation for the electrical connectors, the substrate, and the electronic component, and thus the reliability of the package structure 1 is further improved. Moreover, flux residues may remain within the protective layer without contaminating the surfaces of the substrate and the electronic component, and thus flux cleaning operations can be omitted.

Furthermore, according to some arrangements of the present disclosure, with the operation of dispensing an underfill being omitted, pre-plasma cleaning operation for increasing roughness at the connecting surface between the underfill and the surfaces of the substrate and the electronic component can be omitted, curing operation for the underfill can also be omitted. Therefore, the manufacturing process can be simplified, and the yield can be increased.

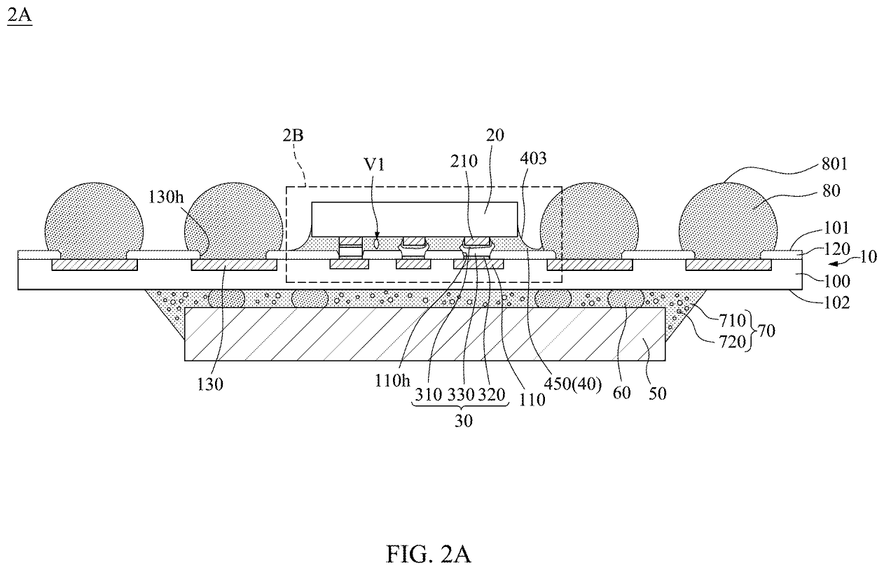

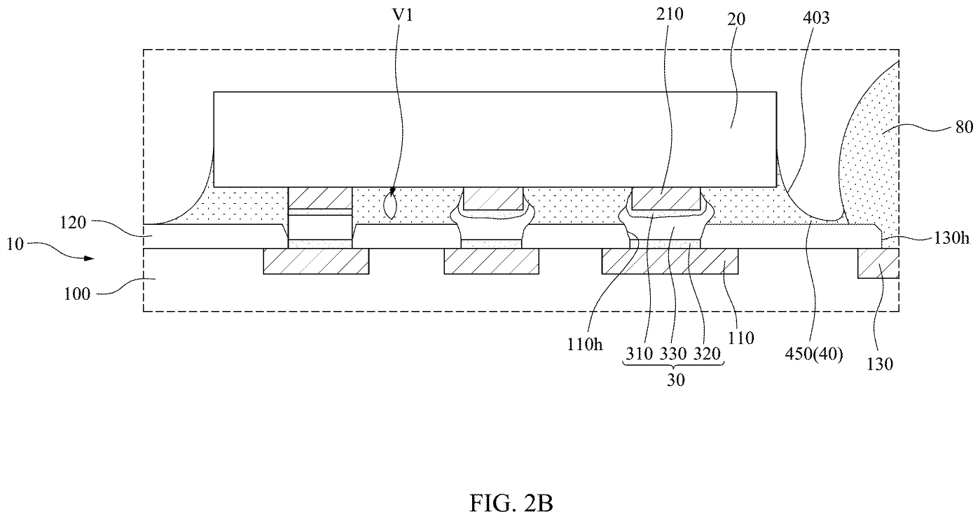

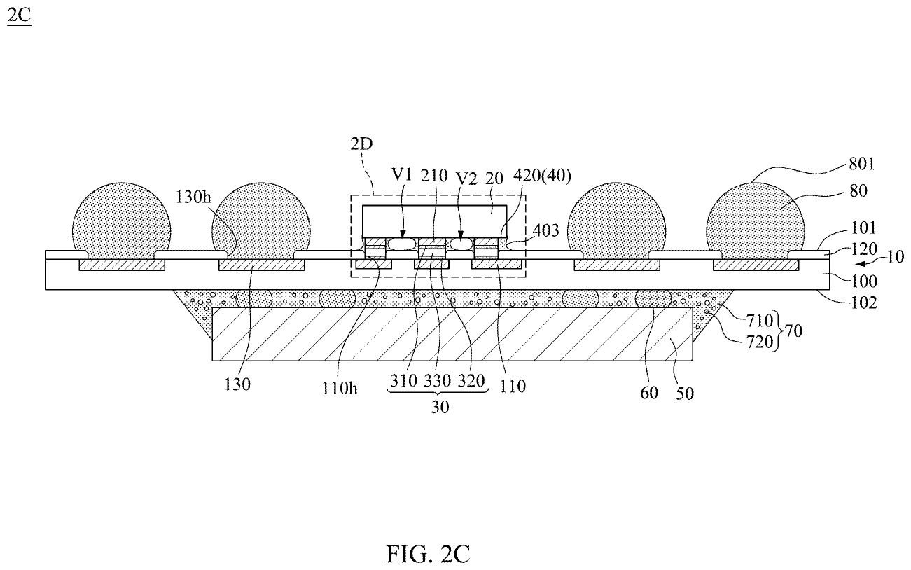

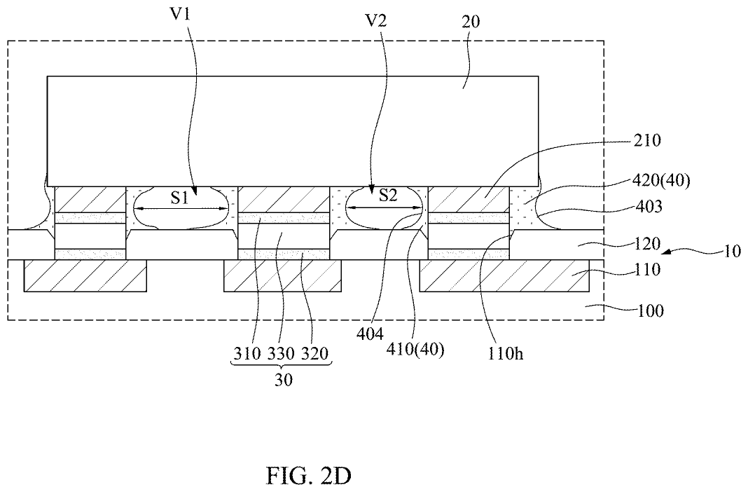

FIG. 2A is a cross-section of a package structure 2A in accordance with some arrangements of the present disclosure. FIG. 2B is a cross-section of a portion of a package structure 2A in accordance with some arrangements of the present disclosure. In some arrangements, FIG. 2B is a cross-section of a portion 2B of the package structure 2A illustrated in FIG. 2A. The package structure 2A illustrated in FIG. 2A is similar to that in FIG. 1, with differences therebetween as follows.

In some arrangements, the protective layer 40 includes a portion 450 having a concave curved surface (e.g., the lateral surface 403) and directly contacting a portion of the electrical contact 80.

In some arrangements, the intermediate layer 310 extends over a portion of lateral surfaces of the conductive pad 210. In some arrangements, the solder element 330 is protruded beyond lateral sides of the intermediate layer 310 and the lateral surfaces of the conductive pad 210.

FIG. 2C is a cross-section of a package structure 2C in accordance with some arrangements of the present disclosure. FIG. 2D is a cross-section of a portion of a package structure 2C in accordance with some arrangements of the present disclosure. In some arrangements, FIG. 2D is a cross-section of a portion 2D of the package structure 2C illustrated in FIG. 2C. The package structure 2C illustrated in FIG. 2C is similar to that in FIG. 1, with differences therebetween as follows.

In some arrangements, the protective layer 40 includes a portion 420 that extends over a portion of the lateral surface 203 of the electronic component 20. In some arrangements, the lateral surface 403 of the portion 420 of the protective layer 40 is partially recessed with respect to the lateral surface 203 of the electronic component 20. In some arrangements, the lateral surface 403 of the portion 420 of the protective layer 40 is partially concave toward the electrical connector 30. In some arrangements, a width S1 of the cavity space V1 is greater than a width S2 of the cavity space V2.

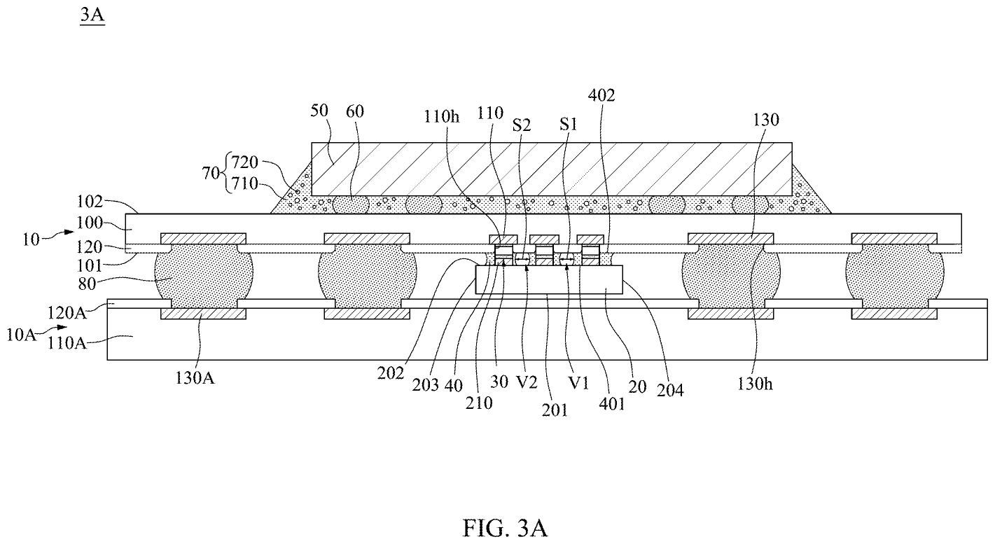

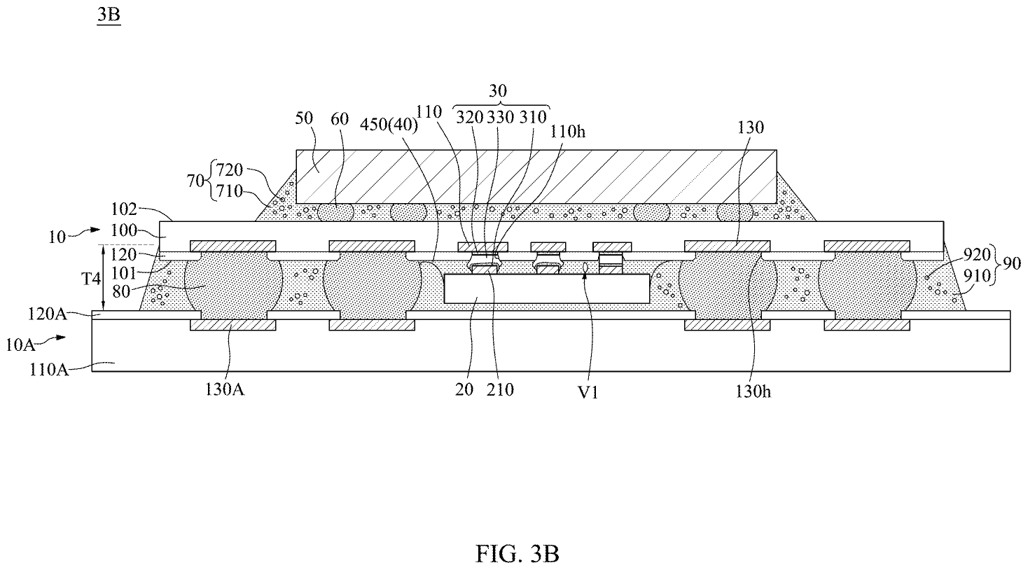

FIG. 3A is a cross-section of a package structure 3A in accordance with some arrangements of the present disclosure. The package structure 3A illustrated in FIG. 3A is similar to that in FIG. 1, with differences therebetween as follows.

The package structure 3A may further include a carrier 10A. The carrier 10A may include, for example, a printed circuit board, such as a paper-based copper foil laminate, a composite copper foil laminate, or a polymer-impregnated glass-fiber-based copper foil laminate. The carrier 10A may include an interconnection structure, which may include a plurality of conductive traces and/or a plurality of conductive vias. The interconnection structure may include a redistribution layer (RDL) and/or a grounding element. In some arrangements, the carrier 10A may include a substrate, such as an organic substrate or a leadframe. In some arrangements, the carrier 10A may include a ceramic material or a metal plate. In some arrangements, the carrier 10A may include a two-layer substrate which includes a core layer and a conductive material and/or structure disposed on an upper surface and a bottom surface of the substrate. The carrier 10A may include a semiconductor wafer or an electronic component. The electronic component may be a chip or a die including a semiconductor substrate, one or more integrated circuit devices and one or more overlying interconnection structures therein. The integrated circuit devices may include active devices such as transistors and/or passive devices such as resistors, capacitors, inductors, or a combination thereof. In some arrangements, the carrier 10A may include one or more conductive elements, surfaces, contacts, or pads.

In some arrangements, the carrier 10A is electrically connected to the substrate 10 through the electrical contacts 80. In some arrangements, the carrier 10A includes a base layer 110A, a dielectric layer 120A, and a plurality of conductive pads 130A. In some arrangements, the conductive pads 130A are electrically connected to the conductive pads 130 through the electrical contacts 80.

FIG. 3B is a cross-section of a package structure 3B in accordance with some arrangements of the present disclosure. The package structure 3B illustrated in FIG. 3B is similar to that in FIG. 3A, with differences therebetween as follows.

In some arrangements, the package structure 3B further includes an underfill 90 between the substrate 10 and the carrier 10A. In some arrangements, the underfill 90 includes a resin layer 910 and a plurality of second fillers 920. In some arrangements, a thickness T4 of the underfill 90 is greater than the thickness T1 of the protective layer 40. In some arrangements, the underfill 90 directly contacts the protective layer 40, and the cavity space V1 is spaced apart from the underfill 90.

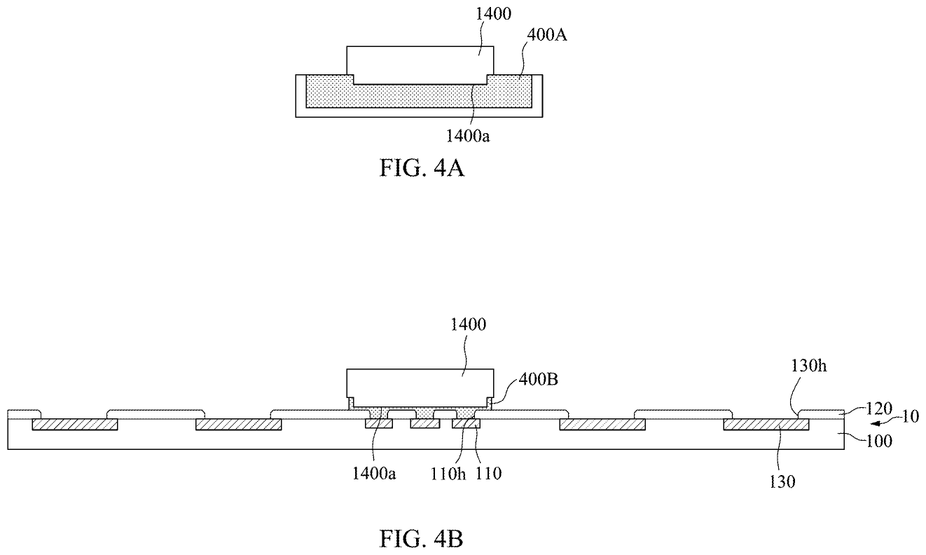

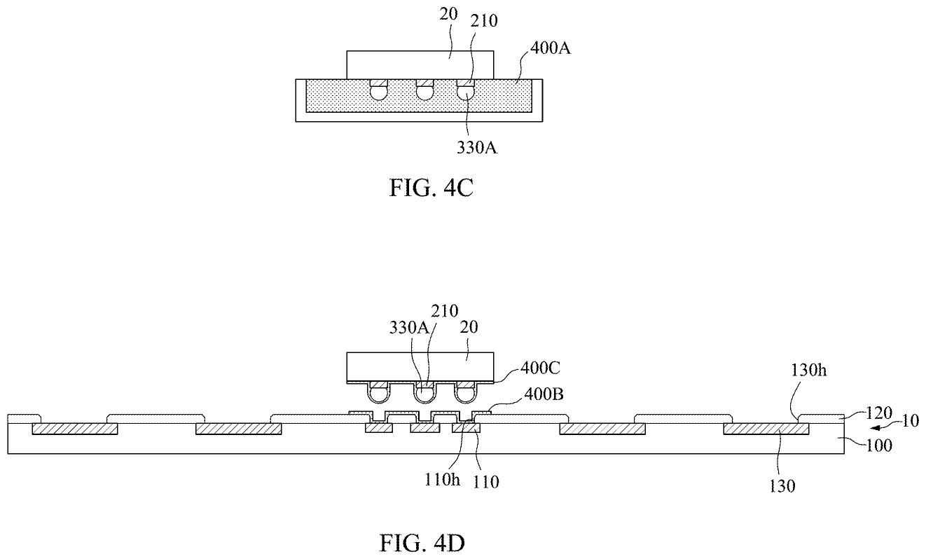

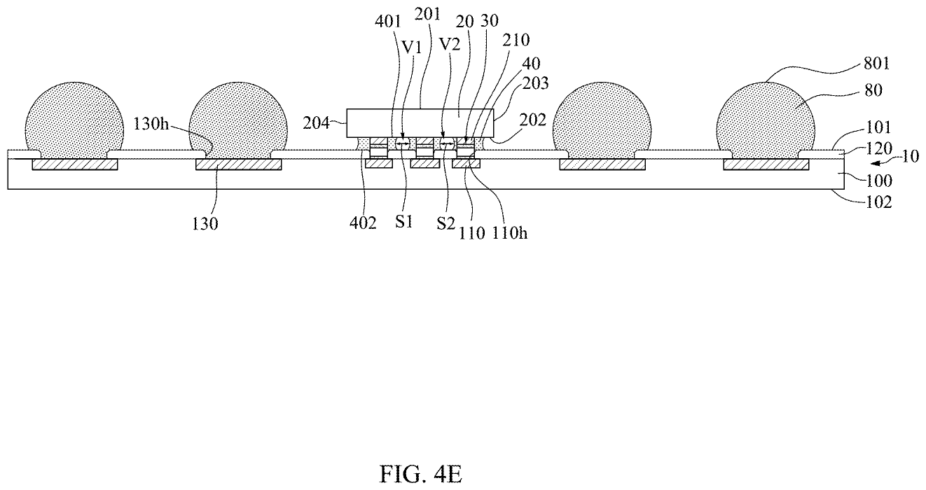

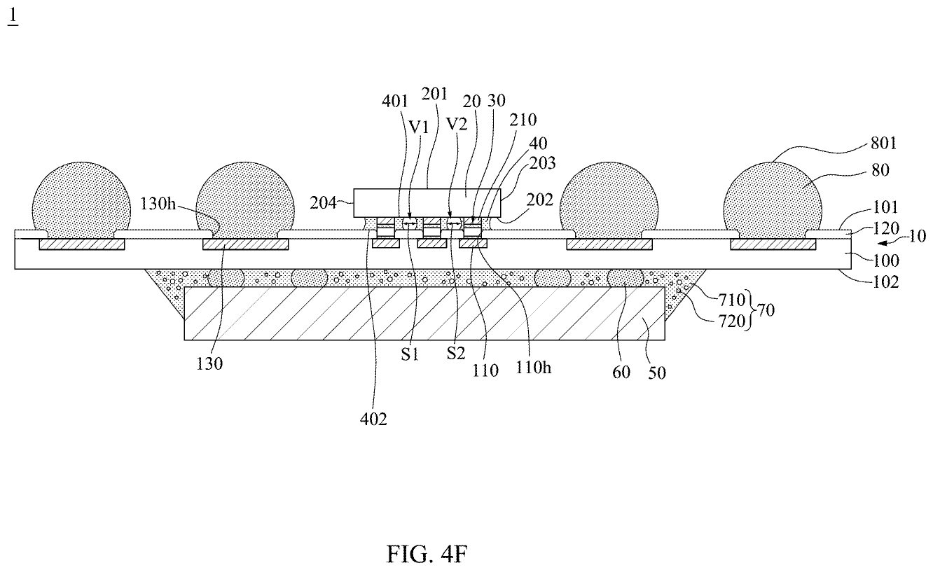

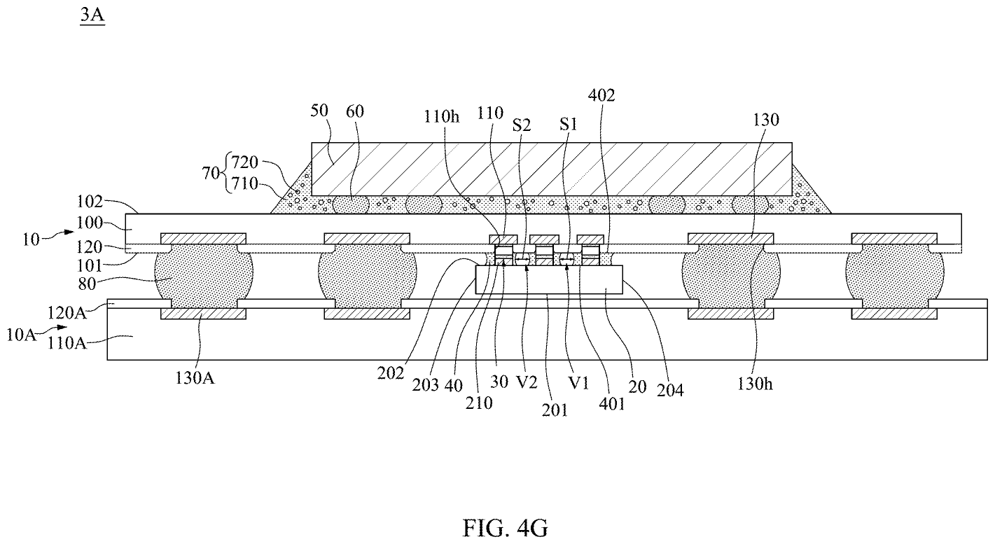

FIG. 4A, FIG. 4B, FIG. 4C, FIG. 4D, FIG. 4E, FIG. 4F, and FIG. 4G illustrate various stages of an exemplary method for manufacturing a package structure in accordance with some embodiments of the present disclosure.

Referring to FIG. 4A, a protective material 400A may be provided, and a stamping member 1400 may be partially immersed into the protective material 400A to obtain a layer of the protective material 400A on a surface 1400a of the stamping member 1400. The protective material 400A may include epoxy flux. The epoxy flux includes an epoxy resin and a solder flux material. In some arrangements, a viscosity of the protective material 400A is equal to or greater than about 20 Pa·S. In some arrangements, a viscosity of the protective material 400A is from about 20 Pa·S to about 35 Pa·S. According to some arrangements of the present disclosure, the protective material 400A has a viscosity within the above range, and thus the viscosity is high enough to have a sufficient amount of the epoxy resin which may form a protective layer in subsequent operations, and the viscosity is low enough to remain a satisfactory processability.

Referring to FIG. 4B, a substrate 10 may be provided. In some arrangements, the substrate 10 includes a base layer 100, a dielectric layer 120 having openings 110h and 130h on the base layer 100, and conductive pads 110 and 130 exposed by the openings 110h and 130h, respectively In some arrangements, the stamping member 1400 with a layer of the protective material may be moved toward the substrate 10 to apply a protective material layer 400B over the conductive pads 110. In some arrangements, the stamping member 1400 is moved toward the substrate 10 to apply a protective material layer 400B in the openings 110h on the exposed conductive pads 110.

Referring to FIG. 4C, an electronic component 20 including conductive pads 210 and solder elements 330A on the conductive pads 210 may be provided, and a protective material layer may be dispensed over the conductive pads 210 and solder elements 330A. In some arrangements, the conductive pads 210 and the solder elements 330A are immersed into the protective material 400A (e.g., “dipping” the conductive pads 210 and the solder elements 330A into the protective material 400A) to obtain a layer of the protective material 400A on surfaces of the conductive pads 210 and the solder elements 330A.

Referring to FIG. 4D, the electronic component 20 with the conductive pads 210 and the solder elements 330A covered with a protective material layer 400C may be moved toward the substrate 10. In some arrangements, the conductive pads 210 and the solder elements 330A covered with the protective material layer 400C are moved toward the conductive pads 110 covered with the protective material layer 400B. In some other arrangements, the operation illustrated in FIGS. 4A-4B may be omitted, and the electronic component 20 with the conductive pads 210 and the solder elements 330A covered with the protective material layer 400C is moved toward the conductive pads 110.

Referring to FIG. 4E, electrical contacts 80 may be disposed on the conductive pads 130, and a reflow operation may be performed on the solder elements 330A to bond the conductive pads 210 to the conductive pads 110. The reflow operation may also connect or bond the electrical contacts 80 to the conductive pads 130. The solder elements 330A may melt and form electrical connectors 30 including solder elements 330 and intermediate layers 310 and 320. The electrical contacts 80 may be solders, and the intermediate layers 310 and 320 may be IMCs. In some arrangements, the electrical contacts 80 may be disposed on the conductive pads 130 before the protective material layer 400B is formed on the conductive pads 110. In some arrangements, the electrical contacts 80 may be disposed on the conductive pads 130 before the protective material layer 400C is formed on the conductive pads 210 and solder elements 330A.

Referring to FIG. 4F, an electronic component 50 may be connected or bonded to the substrate 10 through electrical connectors 60. In some arrangements, an underfill 70 may be disposed to encapsulate the electrical connectors 60. As such, the package structure 1 illustrated in FIG. 1 may be formed.

Referring to FIG. 4G, the package structure 1 illustrated in FIG. 4F may be further connected or bonded to a carrier 10A. In some arrangements, the substrate 10 is bonded to the conductive pads 130A of the carrier 10A through the electrical contacts 80. As such, the package structure 3A illustrated in FIG. 3A may be formed.

According to some arrangements of the present disclosure, the protective material is dispensed by dipping the solder elements 330A and stamping on the conductive pads 110. Therefore, the amount of the protective material is sufficient to provide a satisfactory solder bonding structure, and the protective material is not too much so as to overflow toward the conductive pads 130.

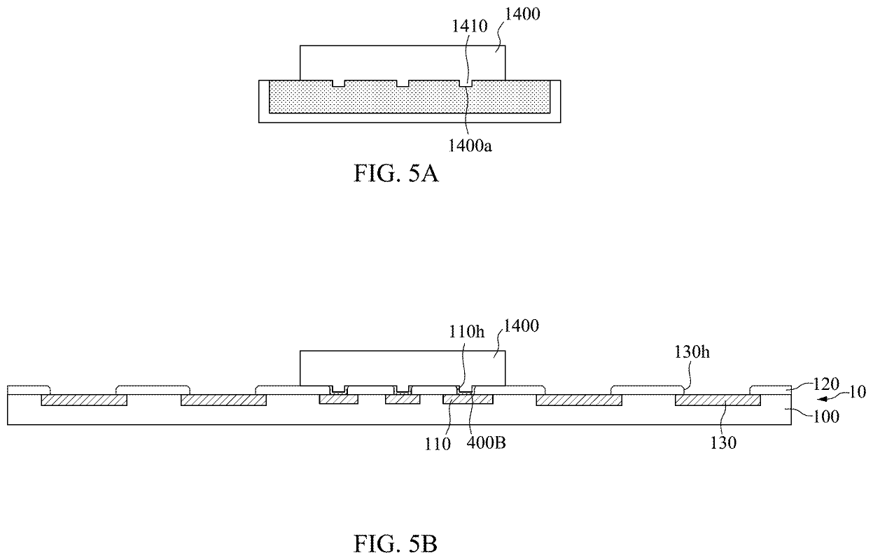

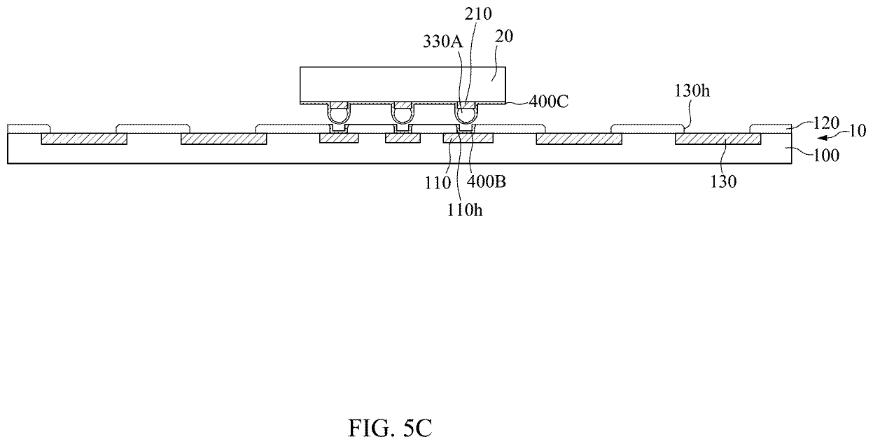

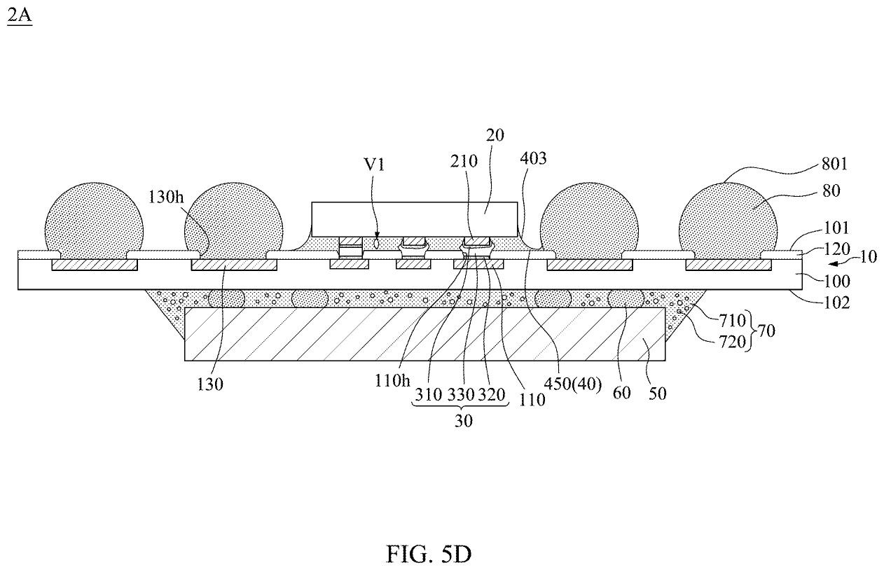

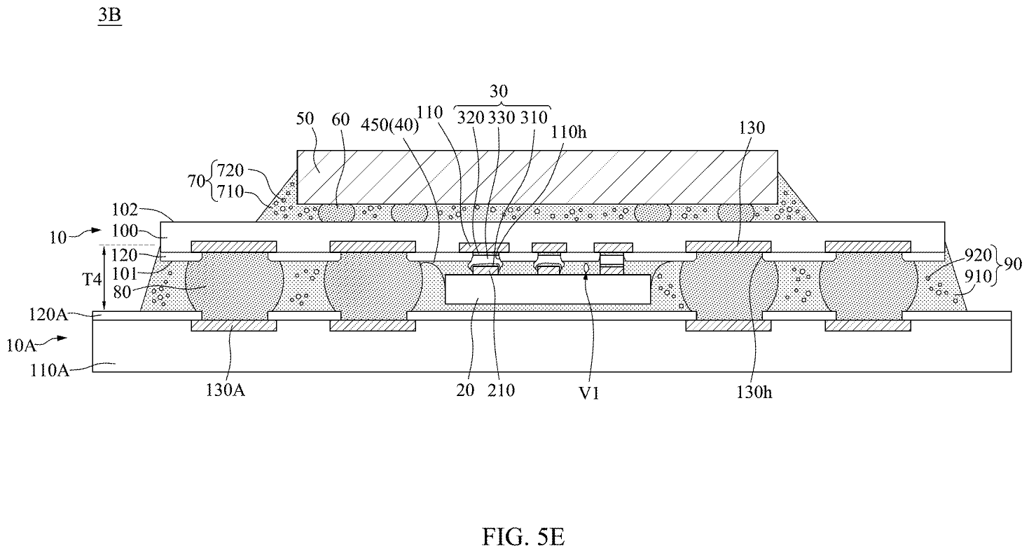

FIG. 5A, FIG. 5B, FIG. 5C, FIG. 5D, and FIG. 5E illustrate various stages of an exemplary method for manufacturing a package structure in accordance with some embodiments of the present disclosure.

Referring to FIG. 5A, a protective material 400A may be provided, and a stamping member 1400 may be partially immersed into the protective material 400A to obtain a layer of the protective material 400A on a surface 1400a of the stamping member 1400. The protective material 400A may include epoxy flux. In some arrangements, the stamping member 1400 includes a stamping head 1410 having a predetermined pattern. The pattern may correspond to a pattern of conductive pads on which the protective material 400A is dispensed subsequently. In some arrangements, the stamping head 1410 includes a plurality of protrusions. The pattern of the protrusions may correspond to the pattern of the conductive pads (e.g., the conductive pads 110) on which the protective material 400A is dispensed subsequently.

Referring to FIG. 5B, a substrate 10 may be provided. In some arrangements, the substrate 10 includes a base layer 100, a dielectric layer 120 having openings 110h and 130h on the base layer 100, and conductive pads 110 and 130 exposed by the openings 110h and 130h, respectively In some arrangements, the stamping member 1400 with a layer of the protective material may be moved toward the substrate 10 to apply a protective material layer 400B over the conductive pads 110. In some arrangements, the stamping member 1400 is moved toward the substrate 10 to apply a protective material layer 400B in the openings 110h on the exposed conductive pads 110. In some arrangements, the protrusions of the stamping head 1410 of the stamping member 1400 may be moved into the openings 110h to apply a protection material layer 400B within the openings 110h on the exposed conductive pads 110. In some arrangements, the protective material layer 400B is dispensed within the openings 110h by allowing the protrusions of the stamping head 1410 to extend within the openings 110h, and the recessed surface of the stamping member 1400 may directly contact the top surface of the dielectric layer 120. In some arrangements, the protective material layer 400B is disposed within the openings 110h and not over the top surface of the dielectric layer 120. The widths of the protrusion may be substantially the same as, greater than, or less than the widths of the conductive pads 110 or the width of the openings 110h.

Referring to FIG. 5C, an electronic component 20 with conductive pads 210 and solder elements 330A covered with a protective material layer 400C may be moved toward the substrate 10. In some arrangements, the conductive pads 210 and the solder elements 330A covered with the protective material layer 400C are moved toward the conductive pads 110 covered with the protective material layer 400B.

Referring to FIG. 5D, electrical contacts 80 may be disposed on the conductive pads 130, and a reflow operation may be performed on the solder elements 330A to bond the conductive pads 210 to the conductive pads 110. The reflow operation may also connect or bond the electrical contacts 80 to the conductive pads 130. The solder elements 330A may melt and form electrical connectors 30 including solder elements 330 and intermediate layers 310 and 320. The electrical contacts 80 may be solders, and the intermediate layers 310 and 320 may be IMCs. In some arrangements, the electrical contacts 80 may be disposed on the conductive pads 130 before the protective material layer 400B is formed on the conductive pads 110. In some arrangements, the electrical contacts 80 may be disposed on the conductive pads 130 before the protective material layer 400C is formed on the conductive pads 210 and solder elements 330A.

Referring to FIG. 5E, an electronic component 50 may be connected or bonded to the substrate 10 through electrical connectors 60, and the substrate 10 may be bonded to conductive pads 130A of a carrier 10A through the electrical contacts 80. In some arrangements, an underfill 70 may be disposed to encapsulate the electrical connectors 60. In some arrangements, an underfill 90 may be disposed to encapsulate the electrical contacts 80. As such, the package structure 3B illustrated in FIG. 3B may be formed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation less than or equal to +10% of that numerical value, such as less than or equal to =5%, less than or equal to +4%, less than or equal to +3%, less than or equal to +2%, less than or equal to +1%, less than or equal to +0.5%, less than or equal to +0.1%, or less than or equal to +0.05%. For example, a first numerical value can be deemed to be “substantially” the same or equal to a second numerical value if the first numerical value is within a range of variation of less than or equal to +10% of the second numerical value, such as less than or equal to +5%, less than or equal to +4%, less than or equal to +3%, less than or equal to +2%, less than or equal to +1%, less than or equal to +0.5%, less than or equal to +0.1%, or less than or equal to +0.05%. For example, “substantially” perpendicular can refer to a range of angular variation relative to 90° that is less than or equal to +10°, such as less than or equal to +5°, less than or equal to +4°, less than or equal to +3°, less than or equal to +2°, less than or equal to +1°, less than or equal to +0.5°, less than or equal to +0.1°, or less than or equal to +0.05°.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 104 S/m, such as at least 105 S/m or at least 106 S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. A package structure, comprising:
a substrate;
a first electronic component over the substrate;
a first electrical connector between the substrate and the first electronic component; and
a protective layer encapsulating the first electrical connector, wherein the protective layer has a first curved lateral surface concave toward the first electrical connector and recessed with respect to a lateral surface of the first electronic component.

2. The package structure as claimed in claim 1, further comprising a second electrical connector adjacent to the first electrical connector, the protective layer is partially spaced apart from the second electrical connector by a cavity space, the protective layer comprises a first portion at a first lateral side of the first electrical connector and a second portion at a second lateral side of the first electrical connector distinct from the first lateral side, and the first portion and the second portion have different widths at an elevation.

3. The package structure as claimed in claim 2, wherein the first portion and the second portion of the protective layer are geometrically distinct from each other.

4. The package structure as claimed in claim 1, further comprising a second electrical connector between the substrate and the first electronic component, wherein the first electronic component has an active surface facing the substrate, the active surface comprises a first region exposed by the protective layer, and the first region is between the first electrical connector and the second electrical connector in a cross-sectional view perspective.

5. The package structure as claimed in claim 1, wherein the protective layer comprises a first protrusion horizontally overlapping the substrate and a second protrusion horizontally overlapping the substrate, and the first protrusion is geometrically distinct from the second protrusion.

6. The package structure as claimed in claim 1, wherein the substrate comprises a first conductive pad electrically connected to the first electronic component and a plurality of second conductive pads at a lateral side of the first electronic component, and a distance between the first conductive pad and one of the second conductive pads is less than a pitch of the second conductive pads.

7. The package structure as claimed in claim 6, further comprising a plurality of second electrical connectors, wherein the substrate is between the first electrical connector and the second electrical connectors, and a pitch of the second electrical connectors is greater than the distance between the first conductive pad and the one of the second conductive pads.

8. The package structure as claimed in claim 6, further comprising an electrical contact disposed on the one of the second conductive pads, wherein an elevation of a top surface of the electrical contact is higher than an elevation of a top surface of the protective layer with respect to the substrate.

9. The package structure as claimed in claim 1, further comprising a second electronic component disposed under the substrate, wherein a width of the second electronic component is greater than a width of the first electronic component.

10. A package structure, comprising:
a substrate having a first surface and a second surface opposite to the first surface;
a first electronic component disposed over the first surface;
a second electronic component disposed under the second surface of the substrate; and
a protective layer between the first electronic component and the substrate, wherein the protective layer has a cavity space at least partially overlapping a path between the first electronic component and the second electronic component, and the cavity space is configured to reduce transmission of heat generated by the second electronic component and transmitted toward the first electronic component.

11. The package structure as claimed in claim 10, wherein the protective layer is free of fillers.

12. The package structure as claimed in claim 11, wherein a corner region of a bottom surface the first electronic component is exposed by the protective layer.

13. The package structure as claimed in claim 10, further comprising:
a first electrical connector between the first electronic component and the substrate; and
a second electrical connector between the second electronic component and the substrate, wherein a thickness of the first electrical connector is less than a thickness of the second electrical connector.

14. The package structure as claimed in claim 13, further comprising an electrical contact disposed at a lateral side of the first electronic component and horizontally overlapping the first electrical connector, wherein a thickness of the electrical contact is greater than the thickness of the second electrical connector.

15. A package structure, comprising:
a substrate comprising a first conductive pad and a second conductive pad, the second conductive pad being exposed by a first opening of the substrate;
an electronic component electrically connected to the first conductive pad; and
a protective layer between the substrate and the electronic component,
wherein the first opening of the substrate is at a first lateral side of the protective layer, and a first ratio of a distance between the protective layer and the first opening of the substrate with respect to a distance between the substrate and the electronic component is less than 25.

16. The package structure as claimed in claim 15, further comprising a plurality of electrical contacts disposed at the first lateral side of the protective layer, wherein a second ratio of a distance between the protective layer and one of the electrical contacts with respect to a pitch of the electrical contacts is less than 0.8.

17. The package structure as claimed in claim 15, further comprising a plurality of electrical contacts disposed at the first lateral side of the protective layer, wherein a second ratio of a distance between the protective layer and one of the electrical contacts with respect to a width of the one of the electrical contacts is less than 0.2.

18. The package structure as claimed in claim 15, further comprising a plurality of electrical contacts disposed at the first lateral side of the protective layer, wherein a second ratio of a distance between the electronic component and one of the electrical contacts with respect to the distance between the substrate and the electronic component is less than 35.

19. The package structure as claimed in claim 15, wherein the substrate further comprises a third conductive pad exposed by a second opening of the substrate, the second opening of the substrate is at a second lateral side of the protective layer, the second lateral side is adjacent to the first lateral side, and a second ratio of a distance between the protective layer and the second opening of the substrate with respect to the distance between the substrate and the electronic component is less than 25.

20. The package structure as claimed in claim 19, wherein the first ratio is different from the second ratio.
